(19) United States
(12) Patent Application Publication
(10) Pub. No.: US 2010/0295168 A1
(43) Pub. Date: Nov. 25, 2010

(54) SEMICONDUCTOR PACKAGE USING CONDUCTIVE PLUG TO REPLACE SOLDER BALL

(76) Inventors: Chien-Te Feng, Shindian City (TW); Aaron Cheng, Taipei (TW)

Correspondence Address: TEXAS INSTRUMENTS INCORPORATED, P O BOX 655474, M/S 3999, DALLAS, TX, 75265, US

(21) Appl. No.: 12/470,134

(22) Filed: May 21, 2009

(51) Int. Cl. H01L 23/52; H01L 21/60

(52) U.S. Cl. 257/698; 438/118; 257/774; 438/121; 257/E23.145; 257/E21.507

(57) ABSTRACT

Exemplary embodiments provide a semiconductor package and methods for its formation. The disclosed semiconductor package can use conductive plug(s) to replace solder ball(s) of a conventional BGA semiconductor package. In one embodiment, the semiconductor package can include a conductive pad disposed over a first dielectric layer having a conductive plug directly extended from the conductive pad through the first dielectric layer and protruded over a surface of the first dielectric layer from about 0 micron to about 50 microns or greater. In various embodiments, arrays of the conductive plugs can be formed for the semiconductor package and can be further connected to a printed circuit board. Various exemplary methods for forming the semiconductor package can include a through-hole metal deposition to form the conductive plugs.

### FIELD OF THE INVENTION

This invention generally relates to a semiconductor package and, more particularly, to a semiconductor package with protruded conductive plug(s), while these protruded conductive plug(s) can replace solder balls at integrated circuit (IC) assembly processes.

### BACKGROUND OF THE INVENTION

One form of packaging for semiconductor devices is known as a ball grid array (BGA) package. Such semiconductor packages involve a substrate used as a chip carrier, wherein the chip is arranged on one surface of the substrate to electrically connect a conductive structure which is formed on the substrate. A plurality of solder balls is mounted on the opposite surface of the substrate to electrically connect the conductive structure. Typically, the solder balls are each attached or placed on the package substrate surface by soldering the balls to a layer of gold. The gold layer rests over a layer of nickel, which rests over a copper pad. In addition, the solder balls are mounted on a printed circuit board (PCB), so that the chip is electrically connected to the PCB through the conductive structure and the solder balls.

Conventional semiconductor packages of BGA devices may use a solder-mask-defined (SMD) or SMD-type of solder ball mounting pad to provide good end-of-line ball shear resistance. In addition, the SMD pad also affords relatively stable control of the x-y positional tolerances of the solder ball.

The solder balls must be soldered essentially two times. The first soldering operation takes place during the attachment of the solder balls to the package (e.g., the layered metal of gold/nickel on the substrate) during package assembly and the second soldering operation involves reflow of the solder balls to the circuit board during device mounting.

### SUMMARY OF THE INVENTION

Applicants have realized that while the conventional semiconductor BGA packages have good end-of-line ball shear resistance and have relatively stable positional tolerances, problems may arise due to the reliability issues between the solder balls and the package substrate (e.g., the conductive pad) and/or during reflows of solder balls to the circuit board.

Conventional semiconductor packages typically use solder balls soldered onto a layered metal by a soldering process. The layered metal includes a gold layer on a nickel layer, where the nickel layer is formed on the conductive pad (or solder pad) of the package. Conventional solder balls are therefore configured not in direct contact with the conductive pad.

Reliability problems of conventional semiconductor packages may be caused by gold embrittlement of the solder ball in a narrow region within the solder ball. This can occur because of too much gold on the substrate or because of insufficient heating, thereby preventing the gold from fully diffusing into the solder ball. Either condition can lead to a brittle region. The brittle region results from a high concentration of gold in the solder within the ball can lead to cracking and separation of the solder ball from the substrate. This separation can lead to a variety of problems such as, for example, open or faulty circuit connections.

Reliability problems of conventional semiconductor packages may also occur at the solder joint during reflows of the solder balls to the circuit board. In order to obtain a complete reflow and to avoid the incomplete solder melt as well as generation of micro cracks, Applicants attempted to raise the heating temperature and the dwell time at peak temperature during heating Failure analysis was also conducted to analyze the failure of the solder joint.

However, “solder splash” was also observed having micro solder balls formed on surface of the solder joint. This may be caused by, i) the solder paste used was not consistent and was too dry or too wet, leading to micro balling during reflow; ii) the solder paste may absorb moisture when abnormal solder paste was normalizing; and/or iii) the temperature ramp rate used was too fast leading to mini explosions. Solder paste shelf life and storage condition were then checked and a lower heating ramp rate was then used to assure proper activation of the flux content of the solder paste.

Another failure of solder joint included “ball-off” problems caused by moisture absorption of the substrate or the conductive pad and/or moisture out-gassing during solder reflow. To solve this problem, proper selection of solder paste and substrate was conducted by the Applicants so as to reduce the out-gassing; extra drying was performed to the substrate before solder reflow; and the circuit board land pad size was optimized to match package land size and to minimize the effects of surface tension mismatch.

A further failure of solder joint that Applicants often encountered included generation of “head-in-pillow” structures due to incomplete wetting/soldering of solder joint during reflow. Such incompletion may be because of surface oxidization of solder ball, surface oxidization of solder paste or wrong selection of solder paste. High quality and high maintenance of these materials in a proper environment was then greatly required. In addition, the reflow profile needed to be fine-tuned.

To solve reliability issues of the conventional semiconductor packages due to such material- and process-problems as described above, the Applicants realized that new materials and methods are needed for semiconductor packages. Specifically, the Applicants discovered that semiconductor packages use conductive plugs have advantages over ones that use solder balls

As disclosed herein, the inventive conductive plug can be a metal plug formed directly on or from the conductive pad by, for example, a metal deposition on surface portions of the conductive pad and along a through-hole in a dielectric layer that is attached to the conductive pad. The conductive plug can protrude outside the through-holes in an equal level of or over the surface of the dielectric layer so as to provide an external contact for the semiconductor package. For example, the conductive plugs can have various protrusion cross sections depending on specific fabrication processes and specific applications.

The conductive plugs can be used to replace conventional solder balls so as to reduce or eliminate problems caused by use of the solder balls as described above. In contrast to conventional semiconductor packaging, the conductive plugs do not need the layered metal for soldering with the conductive pad.

In one embodiment, an array of the conductive plugs can be included for the disclosed semiconductor package, wherein the array of the conductive plugs can further be connected to a printed circuit board (PCB). Semiconductor chips can be arranged on an opposite surface of the package substrate and connected with the PCB using bonding wires, for example.

It is a technical advantage of various embodiments of the invention that the disclosed semiconductor package having conductive plugs formed directly on the conductive pad can address the reliability concerns of conventional packages having solder balls soldered onto the layered metal on the conductive pad. In addition, the replacement of conductive plugs can reduce cost of packaging process, for example, of about 20% or more, as compared to the soldering process of conventional solder balls.

The technical advances represented by the invention, as well as the aspects thereof, will become apparent from the following description of the embodiments of the invention, when considered in conjunction with the accompanying drawings and the novel features set forth in the appended claims.

### BRIEF DESCRIPTION OF THE DRAWINGS

The accompanying drawings, which are incorporated in and constitute a part of this specification, illustrate several embodiments of the invention and together with the description, serve to explain the principles of the invention. In the figures:

FIG. 1 illustrates a schematic cross-sectional view of a portion of an exemplary semiconductor package in accordance with various embodiments the present teachings.

FIG. 2 illustrates a schematic cross-sectional view of a portion of a conventional ball grid array (BGA) semiconductor package.

FIGS. 3A-3G illustrate an exemplary semiconductor package at various stages of fabrication in accordance with various embodiments the present teachings.

It should be noted that some details of the FIGS. have been simplified and are drawn to facilitate understanding of the inventive embodiments rather than to maintain strict structural accuracy, detail, and scale.

### DESCRIPTION OF THE EMBODIMENTS

Reference will now be made in detail to embodiments of the invention, examples of which are illustrated in the accompanying drawings. Wherever possible, the same reference numbers will be used throughout the drawings to refer to the same or like parts.

In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, merely exemplary.

Exemplary embodiments provide a semiconductor package and methods for its formation. The disclosed semiconductor package can use conductive plug(s) to replace solder ball(s) of a conventional BGA semiconductor package. In one embodiment, the semiconductor package can include a conductive pad disposed over a first dielectric layer having a conductive plug directly connected to the conductive pad through the first dielectric layer and protruded over (e.g., above) a surface of the first dielectric layer or having an equal level of (e.g., co-planar with) the surface.

In various embodiments, the semiconductor package can also include a second dielectric layer formed over a conductive pad that is disposed over a first dielectric layer. In various embodiments, each of the first and second dielectric layers can be formed of, for example, a fiberglass, a polyimide tape, a ceramic, an acrylic plastic, a polyimide plastic, an epoxy resin or a mold compound. The first dielectric layer can have at least one patterned through-hole to expose a portion of the conductive pad. A conductive plug can then be formed connecting to and extended from the exposed portion of the conductive pad through the through-hole by, for example, a through-hole deposition of metals. In various embodiments, arrays of the conductive plugs can be formed for the semiconductor package and can be connected to a PCB.

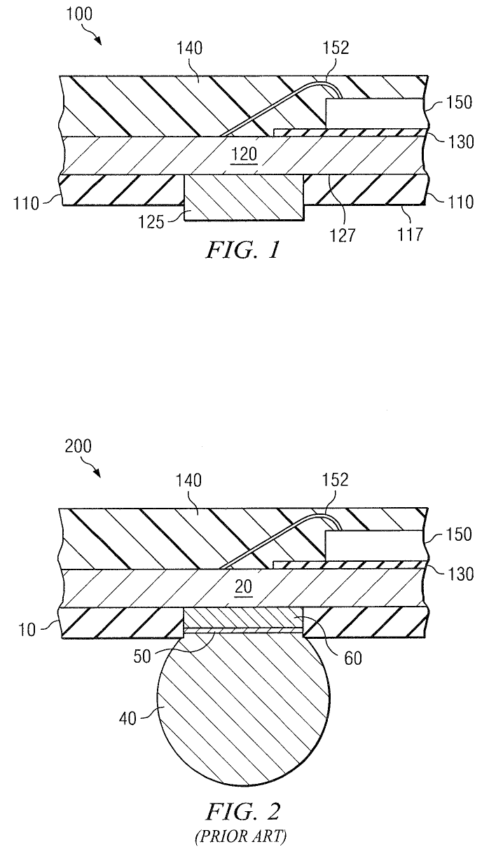

FIG. 1 illustrates a schematic cross-sectional view of a portion of an exemplary package structure 100 in accordance with the present teachings. It should be readily apparent to one of ordinary skill in the art that the structure 100 depicted in FIG. 1 represents a generalized schematic illustration and that other components can be added or existing components can be removed or modified.

As shown in FIG. 1, the disclosed package structure 100 can include a first dielectric layer 110, a conductive pad 120, a conductive plug 125, a second dielectric layer 130 and a mold compound 140.

The conductive pad 120 can be disposed between the first and the second dielectric layers 110 and 130. The first dielectric layer 110 can be patterned to provide one or more through-holes to expose surface portions 127 of the conductive pad 120. The protruded conductive plug 125 can be extended directly from an exposed surface 127 through a through-hole of the first dielectric layer 110 and protruded over or in an equal level of a surface 117 of the first dielectric layer 110. In various embodiments, the protruded conductive plug 125 that is in direct contact with the conductive pad 120 can use the same or different materials as for the conductive pad 120.

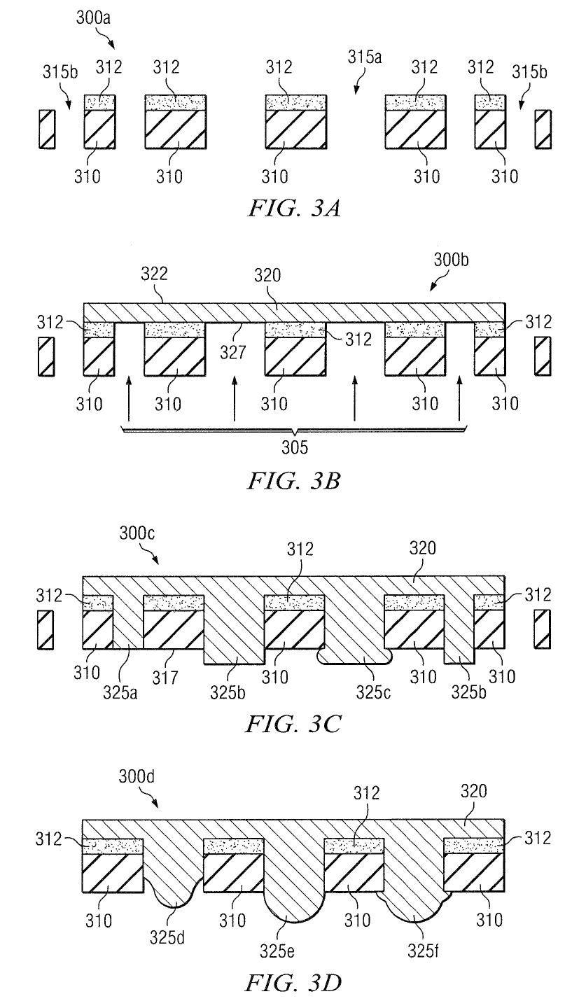

As disclosed, the extruded or protruded conductive plug 125 of the package structure 100 can replace the solder ball that is used in the prior art. For better understanding of the present teachings, FIG. 2 illustrates a schematic cross-sectional view of a portion of a conventional ball grid array (BGA) carrier package structure 200 in accordance with the prior art.

As compared with the structure shown in FIG. 1, the conventional package structure 200 uses a solder ball 40, which is a small eutectic solder ball that is generally about 0.012 inch in diameter and generally formed of a lead/tin alloy. The solder ball 40 is not in direct contact with the conductive pad or the solder pad 20. Typically, the solder ball 40 is attached or placed by soldering the ball to a layer 50 of gold generally having a thickness from about 4 to about 12 micro-inches. The gold layer 50 situates on a layer 60 of nickel having a thickness generally of from about 1.6 micro-inches to about 4.8 micro-inches. The nickel layer 60 situates on the solder pad 20. Typically the solder pad 20 is a copper pad that is in combination of copper, nickel and gold and has a thickness of about 0.02 millimeters. As shown, the solder pad 20 and the insulative mask 10 serve as a solder-mask-defined (“SMD”) solder ball mounting pad attached to the mold compound 140.

The second dielectric layer 130 can be placed on the conductive pad and can include, for example, a sheet of an insulative material, such as fiberglass, polyimide tape, or ceramic. In one embodiment, the second dielectric layer 130 can be a solder resist layer. Electrical components such as semiconductor IC chip or die 150 can then be placed or arranged on surface of the second dielectric layer 130.

The mold compound 140 shown in FIGS. 1-2 can be used to hold the related electrical component, the IC chip 150 and exemplary bond wire 152 in place over the conductive pad 120. The bond wire 152 can electrically connect the IC chip 150 with the conductive pad 120.

The conductive pad 120 or 20 can include, e.g., a layer of one or more metals including, but not limited to, copper, aluminum, gold, silver, nickel, tin, platinum, or combinations thereof. The conductive pad 120 can include laminated and/or plated metal(s). The conductive pad 120 can be patterned metal layer(s) and can include one or more circuit traces within the package radiating outward from it. In one embodiment, the conductive pad can be a copper pad having a combination of copper, nickel and gold. In other embodiments, the conductive pad can have a thickness of, e.g., about 18 microns to about 25 microns.

The first dielectric layer 110 or 10 can be similar to, e.g., a passivation layer or a solder mask in a semiconductor die package, for example, a solder mask in a BGA package. The first dielectric layer 110 can include, for example, an acrylic or a polyimide plastic, or alternatively an epoxy resin. In various embodiments, the first dielectric layer 110 can be silk screened or photo-deposited on the second dielectric material 130 during a formation.

The first dielectric layer 110 can define a through-hole to expose the surface portion 127 of the conductive pad 120. The conductive plug 125, which replaces conventional solder ball 40 shown in FIG. 2, can be directly attached to the exposed surface portion 127, extended through the through-hole and protruded over or in equal level of the exposed surface 117 of the first dielectric layer 110. The extrusion or the protrusion of the conductive plug 125 from the surface 117 can have a protrusion thickness of, for example, about 0 micron or greater. In one embodiment, the conductive plug 125 can have a surface relative to the exposed surface 117 having a zero protrusion thickness over the surface 117. In another embodiment, the protrusion thickness of the conductive plug 125 from the surface 117 can be from about 1 micron to about 50 microns or greater. For example, the conductive plug 125, e.g., a copper plug, can protrude from the surface 117 for about 10 microns.

The conductive plug 125 can use the same or different materials as for the conductive pad 120. The protruded conductive plug 125 can be coupled to the IC chip 150 within the package 100. In an exemplary embodiment, a plurality of conductive plugs 125 can be formed in an array and can be arranged in a grid connected to a circuit board (not shown) such as a PCB.

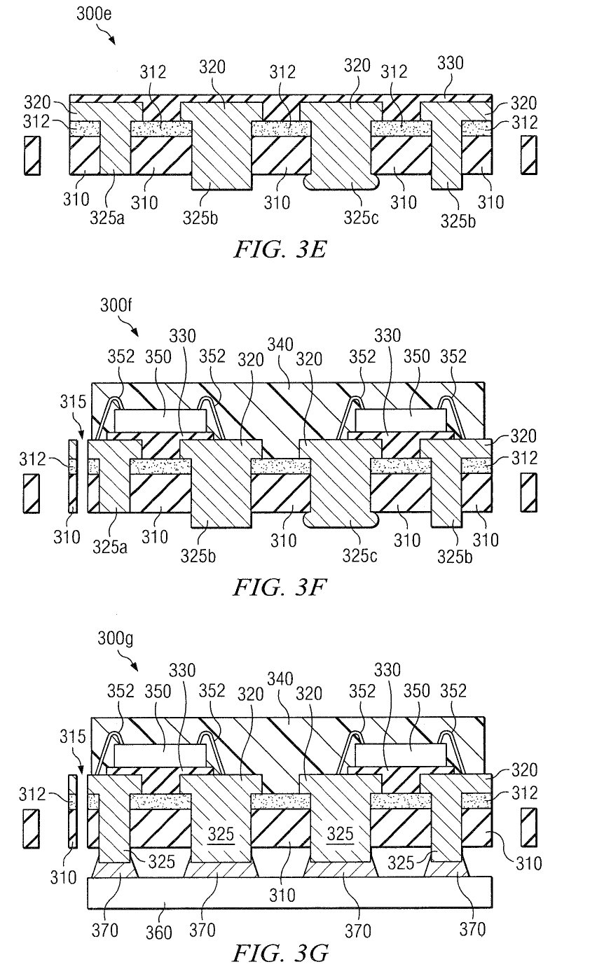

Various embodiments also include methods for forming the disclosed package structure in accordance with the present teachings. For example, FIGS. 3A-3E depict an exemplary package structure at various stages of fabrication in accordance with the present teachings.

In FIG. 3A, the package structure 300a can include a dielectric (insulative) substrate 310 defining a plurality of holes 315a-b formed through the dielectric substrate 310. In various embodiments, an adhesive layer 312 known to one of ordinary skill in the art can be laminated on the dielectric substrate 310 having the plurality of holes formed therethrough in accordance with the dielectric substrate 310. The plurality of holes 315a-b can be through-holes formed through the dielectric substrate 310 and/or through the adhesive layer 312, and can include through-holes 315a and through-holes 315b. In embodiments, the through-holes 315b can include sprocket holes. Various known punching tools can be used to make these holes through the dielectric substrate and/or the laminated adhesive.

In FIG. 3B, an exemplary metal layer 320 can be formed on the package structure 300a of FIG. 3A. The metal layer 320, for example, a copper foil, can be laminated or plated on the adhesive layer 312. In one embodiment, hardening the adhesive 312 by a curing process can follow to attach the exemplary copper layer on the dielectric substrate 310. In various embodiments, the metal layer 320 can cover at least one portion of the top area of the structure 300a, e.g., covering all through-holes 315a. The metal layer 320 can thus have a top surface 322 and a bottom surface 327 that is connected to through-holes 315a.

In various embodiments, a polishing process, such as a chemical, a mechanical, or a chemical mechanical polishing process, can be used to remove impurities from exposed surfaces of the metal layer 320. For example, at 305 of FIG. 3B, micro-etching solution can be used to treat the exposed surfaces 327 of the metal layer 320 through through-holes 315a. In an exemplary embodiment, anti-oxidation agent can be removed from the exemplary copper layer surface using corresponding chemical polishing processes.

In FIG. 3C, conductive plugs, such as metal plugs 325, can be formed through the through-holes 315a from the bottom surface 327 (see FIG. 3B) of the metal layer 320. For example, the metal plugs 325 can be deposited or plated on the bottom surface 327 of the metal layer 320 and through the dielectric layer 310. In addition, the metal plugs 325 can be protruded over a bottom surface 317 of the dielectric substrate 310 having a protrusion thickness of about 0 micron or greater.

In one example of the metal plugs illustrated as 325a in FIG. 3C, the protrusion of the metal plug over the dielectric surface 317 can be about zero, i.e., co-planar with the bottom surface 317 of the dielectric layer 310. In another example of the metal plugs illustrated as 325b-c in FIG. 3C and/or 325d-f in FIG. 3D, the protrusion of the metal plugs over the dielectric surface 317 can have a thickness from about 1 micron to about 50 microns or thicker.

In various embodiments, the protruded portion of metal plugs can have various shapes, regular (see 325b) or irregular (see 325c-f). For example, the metal plugs 325b are shown to have desired regular shapes, which can be formed with aid of a photoresist layer (not shown). For example, the photoresist layer may be patterned on the dielectric surface 317, used as a mask to form the protruded metal plugs 325, and further removed after the formation of the metal plugs 325. In this case, the protrusion thickness of the metal plugs can be determined by the thickness of the patterned photoresist layer. In other specific embodiments, the metal plugs 325 can include a copper plug formed using a coating process known to one of ordinary skill in the art, wherein the copper plug can be coated to protrude from the dielectric layer 310 with irregular shapes for the protrusion portion of the copper plug exemplary illustrated as 325c-f in FIGS. 3C-3D.

In various embodiments, the shape and/or thickness of the protruded portion of each metal plug 325 can be the same or different for a semiconductor device that includes a plurality of metal plugs. In various embodiments, the metal plugs 325 can use the same or different metal material(s) as for the exemplary metal layer 320 and can include any metals, metal alloys or metal-containing polymers used for the conductive pad 120 or 20 of FIGS. 1-2, In an exemplary embodiment when the metal layer 320 is copper, the metal plugs 325 can also include a copper plug.

In various embodiments, prior to the formation of the exemplary metal plugs 325, a supporting plate (not shown), such as a masking tape, can be placed or laminated on the top surface 322 of metal layer 320 so as to provide mechanical support for the formation of the metal plugs 325. Such supporting plate can be removed once the metal plugs 325 have been formed in the corresponding through-holes.

In FIG. 3E, the metal layer 320 can be patterned and etched to remove metal portions associated with the underlying dielectric substrate 310 and to expose surface portions of the cured adhesive 312. Standard photolithography techniques can be used to pattern and etch the metal layer 320 according to specific designs of the package structure. For example, the metal layer 320 can first be coated with a photo resist and then be exposed by UV light through a desired photo mask. The UV exposed photo resist can then be developed and used as an etching mask for the etching process of the underlying metal layer, and finally be removed from the etched metal layer.

In various embodiments, the patterned or arrayed metal layer 320 formed in FIG. 3E can be used as conductive pads for the package structure. In some cases, the conductive pads can be coated with, for example, Ni and Au in order to be electrically connected with, e.g., bonding wires 156.

Still in FIG. 3E, a second dielectric layer 330 can be formed on the entire surface of the patterned metal layer 320. The second dielectric layer 330 can then be patterned to accommodate the arrangement of the IC chip 150 placed thereover and to allow bonding wires 352 to connect the IC chip 350 with the underlying conductive pad 320 through the un-patterned area of the second dielectric layer 330, as shown in FIG. 3F. In this manner, the integrated circuit (IC) chips 350 can be electrically connected to the patterned metal layer 320 through bonding wires 352 with the second dielectric material 330 formed on the patterned metal layer 320. The package shown in FIG. 3E also include a mold compound 340 disposed over the conductive pad 320 to hold the IC chip 350 and the bonding wires 352 in place.

In various embodiments, the second dielectric layer 330 can include a solder resist printed through a screen mask. One or more alignment holes 315 can also be formed for the package structure 300f following the formation of the second dielectric layer 330. In various other embodiments, metal or metal alloys including, for example, a nickel and/or a gold can be plated on any exposed portions of the conductive layer 320 that is un-covered by the second dielectric layer 330.

In FIG. 3G, the metal plugs 325 can provide an external connection and can be electrically connected to a printed circuit board (PCB) 360, for example. Through the PCB 360, the IC chips 350 can be connected to, for example, external inputs and outputs, as known to one of ordinary skill in the art. In various embodiments, the metal plugs 325 can be soldered to join the PCB board 360 using the solder joints 370. Other methods known to one of ordinary skill in the art for connecting the metal plug with PCB can also be used.

In this manner, external connections of IC chips 350 to the PCB 360 can be realized by using the conductive plugs 325 as illustrated in FIG. 3G. However, one of ordinary skill in the art can understand that such external connections can also include one or more solder balls in addition to the use of inventive conductive plugs.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. As used herein, the term “one or more of” with respect to a listing of items such as, for example, A and B, means A alone, B alone, or A and B. The term “at least one of” is used to mean one or more of the listed items can be selected.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor package structure comprising:
a first dielectric layer comprising a through-hole;
a conductive pad disposed over the first dielectric layer;
a conductive plug, wherein the conductive plug extends through the through-hole of the first dielectric layer to directly contact the conductive pad;
an integrated circuit (IC) chip electrically connected to the conductive pad; and
a second dielectric layer disposed between the conductive pad and the IC chip.

2. The package structure of claim 1, wherein the conductive plug protrudes over a surface of the first dielectric layer and wherein the protrusion of the conductive plug over the surface of the first dielectric layer is from about 0 micron to about 50 microns.

3. The package structure of claim 1, wherein each of the conductive plug and the conductive pad comprises one or more metals chosen from a copper, an aluminum, a gold, a silver, a nickel, a tin, a platinum or combinations thereof.

4. The package structure of claim 1, wherein the second dielectric layer comprises a fiberglass, a polyimide tape, a ceramic or a solder resist.

5. The package structure of claim 1, wherein the first dielectric layer comprises an acrylic plastic, a polyimide plastic, or an epoxy resin.

6. The package structure of claim 1, further comprising one or more bonding wires connecting the conductive pad with the IC chip within the second dielectric layer.

7. The package structure of claim 1, wherein the conductive pad is one of a plurality of conductive pads for the package structure.

8. The package structure of claim 1, further comprising a plurality of conductive plugs disposed in an array and a corresponding plurality of conductive pads, wherein each conductive plug of the array is directly in contact with a corresponding conductive pad of the plurality of conductive pads.

9. A method for forming a semiconductor package comprising:
forming a first dielectric layer that comprises a plurality of through-holes;
placing a conductive layer over the first dielectric layer;
forming a conductive plug from the conductive layer in one or more through-holes of the first dielectric layer, wherein the formed one or more conductive plugs are co-planar with a surface of the first dielectric layer or protrude above the surface of the first dielectric layer;
patterning the conductive layer;
forming a second dielectric layer over the patterned conductive layer; and
patterning the second dielectric layer to place a semiconductor chip thereover and to allow a bond wire to connect the underlying patterned conductive layer with the semiconductor chip.

10. The method of claim 9, wherein the formation of the first dielectric layer comprises punching a polyimide film to form a plurality of through-holes.

11. The method of claim 9, further comprising laminating and hardening an adhesive layer between the conductive layer and the first dielectric layer.

12. The method of claim 9, further comprising polishing a surface of the conductive layer in the plurality of through-holes of the first dielectric layer prior to the formation of the conductive plug.

13. The method of claim 9, wherein the formation of the conductive plug comprises a though-hole metal deposition using one or more metals of a copper, an aluminum, a gold, a silver, a nickel, a tin, a platinum and combinations thereof.

14. The method of claim 9, wherein the second dielectric layer comprises a solder resist printed through a screen mask.

15. The method of claim 9, further comprising forming one or more alignment holes following the formation of the second dielectric layer.

16. The method of claim 9, further comprising plating one or more of a nickel and a gold on an exposed portion of the conductive layer that is un-covered by the second dielectric layer.

17. The method of claim 9, further comprising electrically connecting the one or more conductive plugs to a printed circuit board using a solder.

18. A semiconductor package structure comprising:
a first dielectric layer comprising a plurality of through-holes;
a plurality of conductive pads disposed over the first dielectric layer with each conductive pad covering a corresponding through-hole;
a conductive plug extending from each conductive pad through the corresponding through-hole, wherein each conductive plug protrudes over a surface of the first dielectric layer having a protrusion thickness from about 0 micron to about 50 microns;
one or more semiconductor chips electrically connected to the plurality of conducive pads; and
a second dielectric layer disposed between each semiconductor chip and the underlying conductive pad.

19. The package structure of claim 18, wherein each of the conductive plug and the conductive pad comprises one or more metals chosen from a copper, an aluminum, a gold, a silver, a nickel, a tin, a platinum and combinations thereof.

20. The package structure of claim 18, wherein each of the first and second dielectric layers comprises a fiberglass, a polyimide tape, a ceramic, an acrylic plastic, a polyimide plastic, or an epoxy resin.
